(19) United States
(12) Patent Application Publication
(10) Pub. No.: US 2021/0349213 A1
(43) Pub. Date: Nov. 11, 2021

(54) ARBITRARY OPTICAL WAVEFORM GENERATION UTILIZING FREQUENCY DISCRIMINATORS

(71) Applicant: Ivan Grudinin, South Pasadena, CA (US)

(72) Inventor: Ivan Grudinin, South Pasadena, CA (US)

(21) Appl. No.: 17/302,460

(22) Filed: May 3, 2021

Related U.S. Application Data
(60) Provisional application No. 62/704,334, filed on May 5, 2020.

(51) Int. Cl. G01S 17/32; G01S 7/4911; H01S 5/0687

(52) U.S. Cl. CPC G01S 17/32; H01S 5/0687; G01S 7/4911

(57) ABSTRACT

A system where a laser (202) having an input that controls the frequency of laser emission, an optical frequency discriminator (210), and a control system (230) are configured such that the laser frequency can be swept according to a desired function of time. In particular a linear triangular frequency output is achieved which is a repeating sequence of linearly increasing optical frequency and a linearly decreasing optical frequency. The control system relies on a frequency discriminator signal to obtain the information about laser frequency. During generation of repeating swept frequency waveforms the laser frequency remains between the adjacent periodic features of the discriminator optical frequency response. The control system dynamically or iteratively optimizes the laser frequency control signal in order to maintain the desired laser optical frequency sweep.

### BACKGROUND

Light detection and ranging (lidar) systems measure distance to a target in an environment by illuminating the target with laser light and measuring reflected light (lidar return). Lidar is useful for remote imaging in real time for autonomous driving, collision avoidance, navigation, 3D scanning, motion capture and the like. Lidar systems can utilize frequency modulated continuous wave (FMCW) laser sources to measure the radial velocity of the target simultaneously with the distance. Such systems are sometimes called FMCW, Doppler or coherent lidar. The modulation of the FMCW laser source needs to be repeated for each measurement, thus FMCW laser sources with high modulation repetition rate support high rate of measurements.

Of particular importance are FMCW laser sources where laser frequency is changing at a constant rate. If one plots the laser frequency as a function of time, the resulting plot will be a straight line. This represents a single linear sweep of the laser frequency. In a practical FMCW lidar a single distance and velocity measurement can be accomplished with a pair of linear frequency sweeps—one with an increasing laser frequency and one with a decreasing laser frequency. Optical frequency excursion during a single sweep can exceed 1 GHz, and the repetition rate of the sweep pair can exceed 100 kHz, resulting in high measurement data rate.

The high data rate capability makes it possible to scan the beam e.g. across an object such as a moving vehicle and to create a 3D image consisting of a number of recorded points representing the object in the scanned field. FMCW laser radar techniques are described in M.-C. Amann, T. Bosch, M. Lescure, R. Myllyla and M. Rioux, “Laser ranging: a critical review of usual techniques for distance measurement. Opt. Eng. 40, 10-19 (2001), J. Zheng, “Analysis of Optical Frequency-Modulated Continuous-Wave Interference.” Appl. Opt. 43, 4189-4198 (2004), and W. S. Burdic, Radar signal analysis (Prentice-Hall, 1968), Chap. 5. Different lidar types are reviewed and advantages of FMCW are outlined in B. Behroozpour, P. A. M. Sandborn, M. C. Wu and B. E. Boser, “Lidar System Architectures and Circuits,” IEEE Communications Magazine, 55, 135-142 (2017). Also, many aspects of FMCW technique as used with semiconductor lasers (SL) are explained in E. M. Strzelecki, D. A. Cohen, and L. Coldren, “Investigation of tunable single frequency diode lasers for sensor applications. J. Lightwave Technol. 6, 1610-1680 (1988).

Semiconductor lasers (SLs) are attractive for practical applications in FMCW imaging lidar systems because it's possible to electronically control the lasing frequency via the injection current to generate frequency sweeps, including the quickly repeating linear frequency sweeps. Other attractive features of SLs include wide selection of output wavelength, compact size and low cost, narrow spectral line widths of single mode lasers, low power consumption, and ability to convert electric power directly into light. However, precise control of SL frequency has been challenging due to its inherent nonlinearity with respect to injection current. This nonlinearity stems from the SL gain medium dynamics, which becomes especially difficult to control if the direction of frequency tuning is quickly changing and the tuning rate is high. The nonlinearity of diode laser modulation response has been known for a long time. In G. Beheim and K. Fritsch, “Remote displacement measurements using a laser diode.” Electron. Lett. 21, 93-94 (1983) it is shown that a particular SL can only have more or less linear response if its current is swept at under 100 Hz repetition rate.

Prior art methods to linearize SL frequency sweeps and devices producing linear optical frequency sweeps have struggled to operate at high data rate for e.g. imaging applications. For example, an FMCW lidar scanning a scene with a range resolution of under 0.2 m at 200,000 data points per second requires linear optical frequency sweeps of a GHz or more which are repeated every 5 microseconds. For a saw-tooth linear sweep comprising a repeating sequence of linearly increasing optical frequency followed by a linearly decreasing optical frequency a pixel data point can be derived from any pair of adjacent linear sweeps—either an up-down pair or a down-up pair. That is, for a 100 kHz repetition rate of the up-down sweep sequence, the effective data point rate can be twice that rate—200 kHz.

Some prior art methods directly control laser emission frequency by applying distortion to the drive current. Other methods use components external to the laser to measure the waveform resulting from the signal that controls the laser frequency (U.S. Pat. Nos. 7,649,917, 9,559,486). This measurement can be used to improve the linearity of the sweep. The general idea of generating distorted or pre-distorted drive signal can be found in e.g. U.S. Pat. No. 5,436,749.

One method of finding an injection current signal distortion such that the resulting optical frequency sweep in the laser emission is made more linear is described in T. Chen et al., “A Frequency Digital Pre-distortion Compensation Method for FMCW LiDAR System,” paper Th2A.23, Optical Fiber Communication Conference (OFC) 2020. The authors measure frequency response of the semiconductor laser and other system components and compute the distortion of the injection current signal needed to produce the saw-tooth linear optical frequency sweep signal with the laser. This approach was shown to reduce the sweep nonlinearity by a factor of 3 at 10 kHz repetition rate. However, it is not clear if higher sweep repetition rates are supported by the method. Also this method might be difficult to implement in a compact lidar device unit as it requires sophisticated measurement equipment.

There is a group of methods that rely on optical discriminators to measure laser frequency. In general, the transmission or reflection of a discriminator can be periodic with respect to laser frequency changes. This period can be called a free spectral range (FSR). In all of the methods in this group a single sweep of laser frequency covers multiple periods of a discriminator. The methods in this group differ by how they use the measured periodic discriminator signal to control the laser frequency.

Examples of such methods are described in K. Iiyama, L-T. Wang, and K. Hayashi, “Linearizing optical frequency-sweep of a laser diode for FMCW reflectometry,” J. Lightwave Technol. 14, 173-178 (1996), U.S. Pat. Nos. 8,175,126B2, 9,559,486, and 4,893,353A. An optical phase-locked loop (OPLL) can be used for precise control of SL frequency sweeps relying on periodic discriminator output. In OPLL technique, the SL light passes through a discriminator (e.g. an auxiliary interferometer) which generates an electronic beat signal at a frequency proportional to SL frequency tuning rate. This signal is used to stabilize the SL tuning rate by referencing it to a stable oscillator. OPLL-based approaches can provide near ideal linear chirps of up to and above THz span for broadband applications where slow repetition rate is used. However, generation of e.g. approximately GHz sweep span at repetition rates on the order of 100 kHz imposes stringent design requirements on the PLL electronics as shown in a Ph.D. thesis by T. Kim, “Realization of Integrated Coherent LiDAR,” 2019 (https://escholarship.org/uc/item/1d67v62p).

Another method of laser sweep linearization that relies on periodic signals from a discriminator is described in X. Zhang, J. Pouls, and M. C. Wu “Laser frequency sweep linearization by iterative learning pre-distortion for FMCW LiDAR,” Opt. Express 27, 9965-9974 (2019). It relies on a fiber Mach-Zehnder interferometer (MZI) to produce a beat signal at a frequency proportional to the laser tuning rate. A Hilbert transform of the beat signal from the interferometer is used to derive instantaneous laser frequency during the frequency sweep. This instantaneous frequency calculation is then used to iteratively adjust the electronic signal that drives the current through the SL until the frequency sweep as derived from the beat signal measurements matches the desired frequency sweep profile. I found that it is difficult to use this method to obtain quickly repeating sweeps of moderate bandwidth, e.g. about a GHz frequency excursion at e.g. about 100 kHz repetition rate. The Hilbert transform requires many periods of MZI signal per frequency up-sweep (increasing frequency with time) or down-sweep (decreasing frequency with time) in order to reliably reconstruct the instantaneous laser frequency during a sweep. A MZI or another discriminator with an FSR (period) much smaller than 1 GHz must have long optical paths, which makes it difficult to integrate in a robust and cost effective way into compact LiDARs needed for autonomous driving or navigation.

In another group of methods, the laser is tuned over a frequency range that can be smaller than the FSR of a discriminator. Using an optical discriminator such as a Mach Zehnder interferometer (MZI) to generate optical signals to control laser current is mentioned in the US patent application 2020/0025926 A1 paragraphs 0046-0055. However, the application does not provide any disclosure beyond an abstract description and does not claim anything in relation to that description. Using an etalon transmission to implement frequency locking or laser frequency sweeps over a limited set of pre-calibrated values is described in U.S. Pat. No. 7,483,453 B2. However, that approach does not support generation of high repetition rate sweeps or dynamic optimization of the control signals to implement a desired frequency chirp regardless of any thermal or other system non-linearities.

It now becomes evident that there is a need for a simple and low cost FMCW source that can implement very fast laser frequency sweeps with high linearity. Such an FMCW laser source enables compact and robust coherent lidar for multiple applications.

### SUMMARY

The following is a brief summary of the subject matter presented in this application. It is not intended to limit the scope of the claims.

Described herein are various technologies that pertain to FMCW semiconductor laser sources that generate broadband tunable optical radiation with precise control over its frequency. Highly accurate frequency control is achieved through the use of an optoelectronic system. It includes a feedback loop formed by hardware and an algorithm to control the hardware. Such systems can be made of interconnected and interrelated components configured for optimal and robust generation of frequency sweeps with desired sweep functions, in particular linear repeating saw-tooth sweep. The technologies described also pertain to lidar systems based on such swept laser sources.

The source can include a SL that produces a beam that propagates in free space or it can include an SL integrated on a chip platform coupled to on-chip waveguides or it can include a laser, a chip platform and a port that can be used to couple the emission from the laser to the chip platform.

The source can also include an optical frequency discriminator. Any optical component or system with a known dependence of some measurable parameter on optical frequency can serve as a discriminator. For example, a Fabry Perot etalon or resonator represented by an optical dielectric or semiconductor window or a pair of partially reflective mirrors arranged to support optical resonance modes, can be used. In this case the measurable parameter is the optical transmission and optical reflection. The frequency discriminator can also be represented by a waveguide coupled to a waveguide loop or ring or by a Mach-Zehnder interferometer implemented in fiber optics or on a silicon on insulator (SOI) or indium phosphide (InP, III/V) chip platform.

The source can be controlled by a system controller that can include a computing unit or a signal processing system, which controls the components of the source such that it produces the optical signal with a desired frequency sweep. The signal processing can rely on measurements of the signal representing SL power transmitted through an optical frequency discriminator and the signal representing a measure of optical power of the SL. Such measurements can be done with photodetectors, amplifiers, filters and other supporting electronic components.

Pursuant to various embodiments, an FMCW laser source having a wide frequency range and precise control of the frequency of optical emission can include a semiconductor laser with the injection current input. Providing a current into this input can result in an optical laser output with optical frequency that depends on the injection current in a nonlinear way. A digital signal generator is coupled to control the output of the semiconductor laser by varying the injection current input thereto, with the measurement system including a signal divider receiving the laser output and providing a major laser power output signal and a feedback signal therefrom. The isolator can be included right after the SL to prevent any reflected light from returning to the laser. Another signal divider can be included that receives the feedback signal and provides the power sensing signal and the frequency sensing signal. In this arrangement the power of both signals after the second divider remains proportional to major laser power output signal. An optical discriminator receives the frequency sensing signal from the second beam divider and provides an optical discriminator signal that varies in accordance with the laser output frequency. The optical discriminator signal is converted into electronic discriminator signal by a photodetector and all necessary electronics. The power sensing signal is received by another photodetector. The electrical signals derived from the detectors that receive the power sensing and the optical discriminator signals are measured and processed in the signal processing system to create the voltage signal. This voltage signal controls the laser injection current via a current source. The current source has a modulation input that can be controlled by the voltage signal to produce laser injection current modulation. The current source can also receive data communication signals from the signal processing system. These signals can instruct the current source to output a predetermined constant injection current bias value added to the modulation current. The algorithm in the signal processing system adjusts the voltage signal until the desired laser frequency sweep is obtained. In cases where laser output power does not depend on the injection current, such as in the case of lasers consisting of a lasing section and a gain section, the power monitoring arrangement may not be required.

Pursuant to various embodiments a lidar system can include a FMCW laser source and a signal divider that provides a local oscillator (LO) signal and a major lidar output signal. The lidar system can include a focusing lens in the LO signal path. The lidar system can also include an optical circulator that passes the major lidar output signal through and deflects the optical lidar return signal into another direction. The device can include a telescope for beam shaping and can include beam steering components and a protective window filter that blocks radiation outside of the SL operating wavelength. The output of the circulator passes through the telescope, beam steering and window components on its way to a remote target. The major lidar output signal illuminates the target and a portion of this signal is scattered by the target to become the optical lidar return signal. A portion of this return signal then reaches the circulator which now deflects it toward an optional focusing lens. The lidar device can also include a beam splitter which also acts as a beam combiner. It receives the LO signal and splits it in two parts. One part is received by a signal detector and another part is received by another signal detector. The splitter/combiner also receives the lidar return signal and splits it into two parts that reach the two signal detectors. The detectors are arranged in what is known as a balanced detector configuration and provide the electronic lidar return signal. For background on balanced detector configuration see e.g. R. Stierlin, R. Baettig, P. Henchoz, et al. “Excess-noise suppression in a fibre-optic balanced heterodyne detection system.” Opt. Quant. Electron. 18, 445-454 (1986). Some or all of the components mentioned here can be replaced with their integrated photonic counterparts if the lidar system and the FMCW source are implemented on a chip platform.

The above summary is not an extensive overview of the systems and/or methods discussed herein. It represents a simplified overview that provides a basic understanding of some aspects of the systems and/or methods discussed here. It is not intended to identify key/critical elements or to outline the scope of such systems and/or methods. Its only purpose is to provide some concepts in a simple form as an introduction to the more detailed description that is presented later.

### BRIEF DESCRIPTION OF THE DRAWINGS

FIG. 1 illustrates a schematic representation of discrete-optical discriminators.

FIG. 2 illustrates a block diagram of an exemplary FMCW laser source.

FIG. 3 illustrates exemplary signals at the beginning of FMCW laser source sweep optimization.

FIG. 4 illustrates a schematics of an exemplary FMCW laser source implemented on a chip platform.

FIG. 5 illustrates an exemplary flowchart of a computer program that controls the FMCW laser source.

FIG. 6 illustrates exemplary optimized signals of FMCW laser source.

FIG. 7 illustrates a schematics of an exemplary lidar system utilizing discrete optical components.

FIG. 8 illustrates a schematics of an exemplary lidar system utilizing integrated and discrete optical components.

FIG. 9 illustrates a schematics of an exemplary signal processing computer system.

### DETAILED DESCRIPTION

Some embodiments provide a FMCW laser source that is simpler than prior-art sources, or provide faster frequency sweep repetition rates. Some or all embodiments provide a source that is less expensive or easier to make than prior-art sources. In addition to such advantages, the embodiments also provide optical frequency sweep with linear chirp having low deviation from linearity, e.g. less that 1%. Embodiments described here enable low cost imaging FMCW lidar and chip-based FMCW sensors which can be produced in large quantities for the advanced driver assistance systems (ADAS), virtual reality, robotics, autonomous driving and flying, and other applications. These and other benefits of one or more aspects will become apparent from a consideration of the ensuing description and accompanying drawings.

Technologies pertaining to generation of optical beams with frequency swept in a desired way are now described with reference to the drawings. In the following description specific details are set forth in order to provide a thorough understanding of one or more aspects. It may be evident that such aspects may be practiced without these specific details. In other instances, well-known structures and devices are shown in block diagram form in order to help describing one or more aspects. Also, functionality that is described as being carried out by certain system components may be performed by multiple components. Similarly a component may be configured to perform functionality that is described as being carried out by multiple components.

Moreover, the term “or” is intended to mean an inclusive “or” rather than an exclusive “or.” The phrase “A employs X or Y” is intended to mean any of the natural inclusive permutations, unless specified otherwise or clear from context. Moreover, the articles “a” and “an” as used in this specification and claims should generally be construed to mean “one or more” unless specified otherwise or clear from the context.

Here we use the terms “component” and “system” to encompass computer-readable data storage that is configured with computer-executable instructions that cause certain functionality to be performed when executed by a processor. The computer-executable instructions may include a routine, a function, or the like. The terms “component” and “system” are also intended to encompass one or more optical elements that can be configured or coupled together to perform various functionality with respect to an optical signal. It is also to be understood that a component or system may be localized on a single device or distributed across several devices. Further, as used herein, the term “exemplary” is intended to mean “serving as an illustration or example of something.”

In some embodiments, an optical discriminator such as a Fabry-Perot etalon or a fiber-based interferometer can be used to directly obtain information about the instantaneous frequency of a laser. This information can then be used to control the laser bias current to generate linear frequency sweeps suitable for FMCW ranging. The integrated photonics counterparts of such etalons include a waveguide loop resonator, a waveguide interferometer such as a Mach-Zehnder, a resonator such as a whispering galley mode resonator, an atomic transition line of a vapor cell, or any other component with known dependence of some measurable parameter on optical frequency.

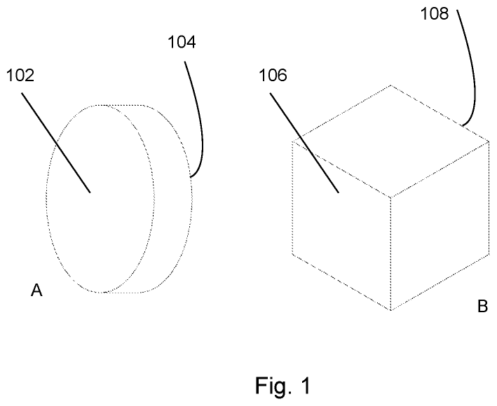

For example, a Fabry-Perot (FP) discriminator was successfully used to generate linear sweeps using the method described here. The FP is a flat silicon window with no coating applied. Referring now to the drawings, FIG. 1-A illustrates a round optical window with plane-parallel flat uncoated surfaces 102 and 104 made of silicon, or an arbitrary shaped e.g. cubic window with similar surfaces 106 and 108 as shown in FIG. 1-B can be used. The window input and output surfaces (102, 104) or partially reflecting mirrors can be planar or non-planar. Planar and non planar window surfaces or mirrors can form what is known as a FP resonator that functions as a discriminator. The thickness of such FP discriminator can be e.g. between 0.5 and 5 mm.

For clarification, “optical frequency sweep” means a change of optical frequency ƒ according to an arbitrary function F of time t. The function F is called “chirp”, and the sweep can be described as having linear chirp if F(t)=ƒ₀+kt, where ƒ₀ is an initial frequency and k is the constant rate of frequency change. Linear up-chirp is defined as F(t)=ƒ₀+kt, k>0, and a linear down-chirp is defined as F(t)=ƒ₀+kt, k<0. A linear saw-tooth sweep is defined as a sequence of a linear up-chirp and a linear down-chirp that is repeating at some repetition rate.

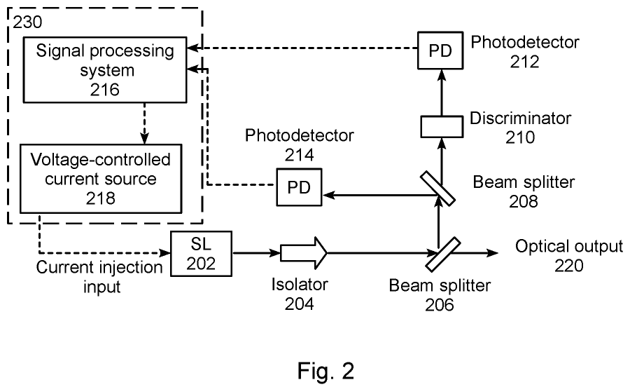

An embodiment of an electronically tunable semiconductor laser system that can function as an FMCW source is shown in FIG. 2 as a block diagram. It includes a semiconductor laser (SL) 202 with an optical output tunable by injection current. The laser can have a section separate from the laser gain section that can be controlled by a signal that causes the laser output frequency to change. It can include a gain section that follows the lasing section and provides gain and suppresses the changes in laser intensity. The SL can be a distributed feedback (DFB), a distributed Bragg reflector (DBR) or another type of laser. It can emit laser radiation having any useful wavelength from deep UV to THz, for example a wavelength around 1550 nm or 1310 nm. The SL assembly may incorporate temperature control and sensing elements, and beam focusing optics such as a lens. The SL output optical frequency and power are responsive to the injection current provided here by the voltage-controlled current source (VCCS) 218. The current supplied by the VCCS to the laser is a constant bias current that can be programmable, plus a modulation current proportional to a control voltage provided to the VCCS 218 by the signal processing system 216. The laser beam can pass through an isolator 204 that prevents any scattered or reflected laser light from returning the the laser. Such back-scattered light can destabilize the laser operation and affect its optical frequency during operation. The isolator may also be integrated with the SL assembly or an isolating function may be incorporated into laser design or waveguide design. A minor part of the output emission of the swept SL 202 (e.g. 1-10%) is split by the beam splitter/divider 206 to form the feedback signal. This beam splitter 206 passes a major part of SL output emission undisturbed to form the optical output of the system 220. Another beam splitter/divider 208 separates a fraction of the feedback signal (e.g. 5-50%) and deflects it onto another path to form an optical power monitor signal which is received by a power monitoring photodetector 214. The other part of the feedback signal which passes through the beamsplitter 208 forms a frequency monitoring signal which is received by an optical discriminator 210. The discriminator can be a Fabry-Perot etalon oriented such that the optical signal arrives at the etalon input surface at about normal incidence

When frequency monitoring signal passes through the discriminator or is reflected by the discriminator, it acquires variation with a predetermined dependence on optical frequency. A transmission coefficient of a Fabry-Perot etalon is a ratio of the transmitted optical power to the incoming optical power. The transmission is a periodic function of laser optical frequency. This dependence of transmission on frequency is the reason why etalons are examples of broad category of optical discriminators—they can help discriminate one frequency from another. In one embodiment a 12.5 mm diameter, 3 mm thick uncoated flat polished silicon window was used as an etalon. A window can be implemented in a variety of dimensions and shapes, can be cubic or similar, with diameter or cross section from e.g. 0.5 to 25 mm and with thickness e.g. from 0.1 to 10 mm as schematically shown in FIG. 1.

In one embodiment of a discriminator, the amount of optical power transmitted through the discriminator depends on optical frequency. Transmitted optical power forms a frequency monitoring signal which is received by a discriminator transmission monitoring photodetector 212. The electronic signals from the photodetectors 212 and 214 are recorded by a signal processing system 216 which also generates new signals which control the current source 218. Detector 212 can be a separate component or can be part of discriminator 210, the same applies to detector 214 and beam splitter 208. The signal processing system 218 and the voltage-controlled current source 218 can be represented by physical blocks inside the system controller 230, or can be functional elements of the system controller. The system controller 230 can have additional functionality for e.g. controlling the temperature of the laser 202, the discriminator 210, and of any other system component. The current source 218 can be controlled digitally or by a control voltage. All the components described above can together be considered an example of an opto-electronic digital feedback loop.

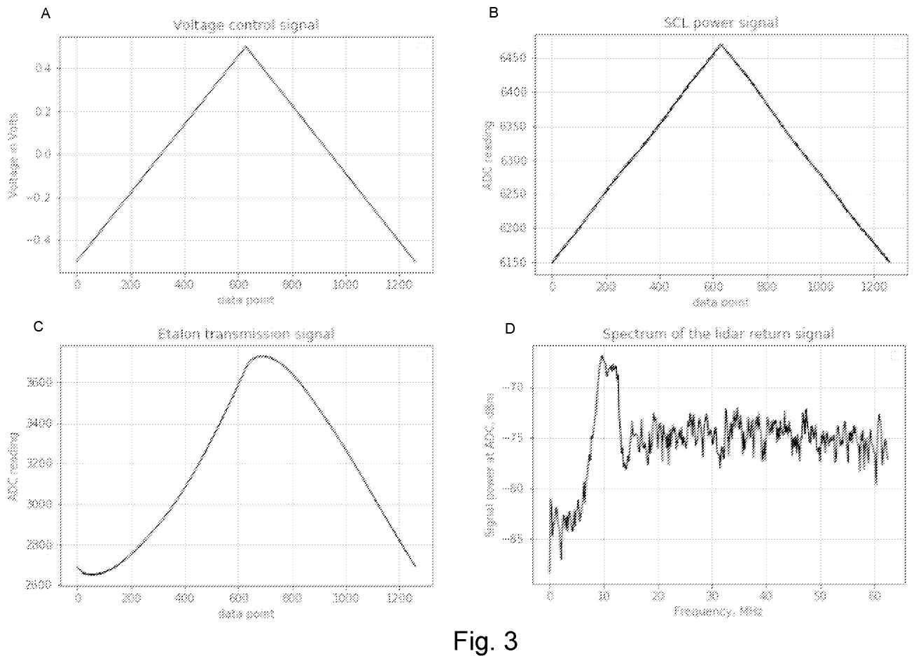

In order to initiate generation of arbitrary optical frequency sweeps from the SL in this embodiment, the signal processing system 216 creates a modulation signal which is a periodic linear saw-tooth-shaped voltage, one period of which is shown in FIG. 3-A. This voltage is applied to the modulation input of the current source 218. The current source generates the injection bias current and adds the modulation current. The magnitude of the bias current is typically much larger than the amplitude of current modulation. For example, a bias current can be 100-200 mA and the modulation of the current due to the above voltage signal can be around 5-10 mA. The combined signal is applied to the current injection input of the SL 202, resulting in laser emission that is modulated in power and frequency. This modulation is nonlinear with respect to the applied modulated injection current. The power modulation is measured by the power monitoring detector 214. The frequency sensing beam is received by the etalon 210 which acts as a frequency discriminator producing a frequency dependent power signal which is measured by detector 212. Thus, etalon transmission signal is affected by both etalon transmission as a function of optical frequency and by the modulation of optical power of the laser. The purpose of the power measurement by detector 214 is to cancel the effect of power modulation from the signal produced by the detector 212.

In some embodiments, the second signal divider 208 can be replaced by a circulator that, in addition to passing the feedback signal to the optical discriminator 210, also receives the signal reflected from the discriminator and directs that reflected signal to a power sensing photodetector 214. The use of the circulator makes it possible to increase measurement precision and to synthesize the measure of the feedback signal power by adding the values of the measurements provided by detectors 214 and 212.

The fraction of optical power transmitted by a non-ideal Fabry-Perot etalon is given by:

$$\frac{{P}_{transmitted}}{{P}_{incident}} = η = ( 1 - p ) \frac{{( 1 - R )}^{2}}{4 R {sin}^{2} ( 2 π d f n / c ) + {( 1 - R )}^{2}} + p , \qquad ( 1 )$$

where R is a power reflection coefficient of etalon mirrors/surfaces (assumed same for both mirrors for clarity), d is the distance between the reflective surfaces, ƒ is the optical frequency, n is the refractive index of the material filling the space between the reflective surfaces. Etalon material refractive index n depends on optical frequency ƒ, temperature and pressure unless the space between the reflective surfaces is vacuum with n=1. c=299,792, 458 m/s is the speed of light in vacuum. p is the fraction of SL power that does not resonate within the etalon due to non-ideal mode matching or misalignment. In practice, p can be found from Eq. (1) if R and the minimum value of etalon transmission ηₘᵢₙ are known:

$$p = \frac{( {η}_{min} - 1 ) {( 1 - R )}^{2} + 4 R {η}_{min}}{4 R} . \qquad ( 2 )$$

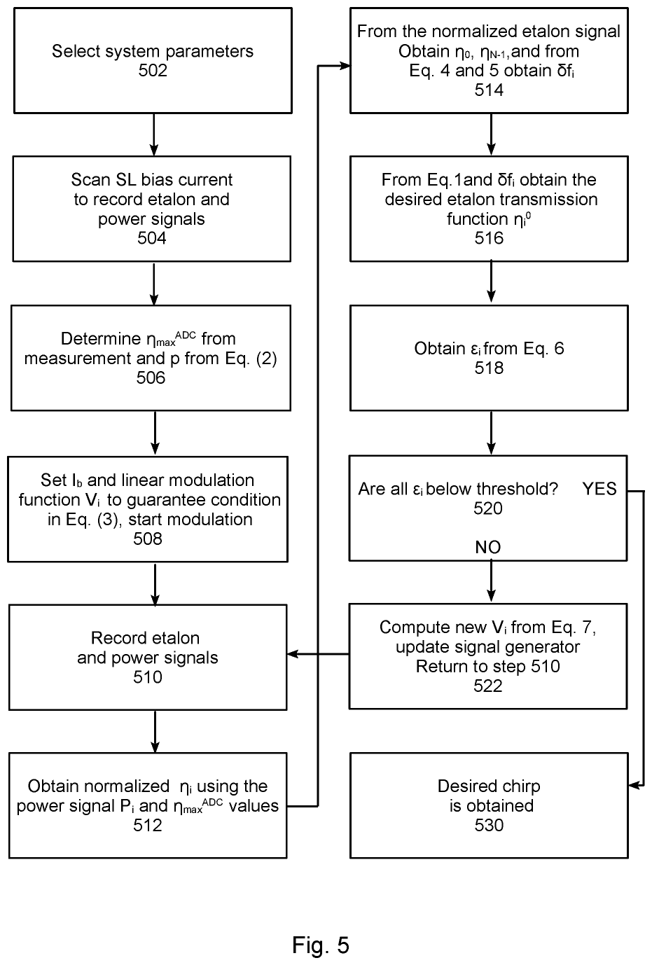

In order to generate frequency sweeps with arbitrary chirp function the algorithm can include the calibration steps 502-508 in FIG. 5. The signal processing system 216 controls the current source 218 to produce a relatively slow linear sweep of SL bias current. The sweep forces the SL 202 to change the emission optical frequency while the system records signals obtained by detectors 212, called the “electronic discriminator signal” and 214 called the “electronic power signal”. The current sweep is selected in step 502 and 504 such that according to Eq. 1 the etalon transmission varies sufficiently to record at least one maximum and one adjacent minimum of the etalon transmission function Eq. 1. These values are recorded at step 504, e.g. in ADC counts or bins by the signal processing system 216: ηₘᵢₙ^{ADC}, ηₘₐₓ^{ADC}. Also, Pᵢ is the digitized electronic power sensing signal and ηᵢ^{ADC} is the digitized electronic etalon transmission signal. In other words the electronic signals are digitized and stored in computer memory of the signal processing system at step 504. The digitized etalon transmission values ηᵢ^{ADC} are divided by the digitized power signal Pᵢ and by the maximum transmission value of the etalon signal ηₘₐₓ^{ADC} one-by-one (for each i) in order to obtain the minimum transmission value ηₘᵢₙ normalized to 1 as in Eq. 1. This value is substituted into Eq. 2 to obtain p at step 506.

Eq. (1) is a periodic function of frequency ƒ=ƒ_{N}+δƒ, where

$${f}_{N} = \frac{c N}{2 dn}$$

corresponds to frequency of the etalon transmission peak number N. For a given N, if

$$0 < δ f < \frac{c}{4 d n} , or 0 > δ f > - \frac{c}{4 d n} \qquad ( 3 )$$

the etalon transmission is a single-valued function of δƒ (i.e. it provides only one value of η for each possible δƒ). In other words, the etalon transmission remains be phe N-th peak and the following

$$( 0 < δ f < \frac{c}{4 d n} )$$

or the preceding

$$( 0 > δ f > - \frac{c}{4 d n} )$$

transmission minimum. This can be achieved at step 508 by constraining the SL current to a certain range. This range can be found in the calibration step outlined above or by empirically adjusting the SL temperature and offset bias current.

Since the etalon function is now single-valued, it is possible to invert it to find δƒ as a function of η(ƒ):

$$δ f = \frac{c}{2 π d n} arcsin \sqrt{\frac{{( 1 - R )}^{2}}{4 R} \frac{1 - η}{η - p}} \qquad ( 4 )$$

Thus, the above equation reconstructs laser frequency changes δƒ(t) from a measurement of discriminator transmission η(t). Similar sets of equations describing other examples of discriminators can be derived.

Reconstruction of laser frequency from discriminator transmission can be used in so-called resampling methods for FMCW lidar. The non-linear frequency sweep can effectively be made linear by resampling of the digitized lidar return signal relying on the knowledge of instantaneous frequency from the discriminator. The method would be as follows. Apply linear bias current modulation to the laser. Record the interference signal between the LO signal and the lidar return signal from the remote target on the detector and digitize it by sampling at a constant rate. Record the etalon and power signals ηᵢ^{ADC}, Pᵢ simultaneously with the linear current sweep. Reconstruct δƒ(t) from those signals and resample the interference signal at a rate which is a function of δƒ(t) and other parameters. Resampling is a computational operation. The resampled lidar signal will result in a narrow lidar return spectral peak after the Fourier transform.

The linear bias current modulation signal and the bias offset value are generated in step 508 such that the SL frequency is in the correct range of Eq. 3, according to the calibration steps above. The modulation amplitude is also selected such that SL frequency remains in the range of Eq. 3 (e.g. on the slope of the etalon transmission peak). A linear, discrete-valued modulation voltage function is made of an up-chirp Vᵢ=−Vₘ+ki followed by a down-chirp Vᵢ=Vₘ−ki, where i∈[0, N−1] is the data point index, Vₘ is the modulation amplitude, and k=2Vₘ/(N−1). The voltages are calculated and produced by the signal processing unit 216 such that it produces S voltage values per second and repeats the sequence of up and down voltage sweeps as long as needed at a repetition rate of S/2N. The voltage signal is received by the voltage controlled current source 218 which converts the control voltage to SL 202 modulation current with some coefficient of conversion (a) and adds it to the constant bias current which it sets according to a command from the signal processing unit. For example: I_{SL}=I_{b}+aVᵢ.

An SL output frequency is a nonlinear and generally not directly known function of current: ƒ₀+δƒ(t)=Fₘ(I_{b}+Iₘ(t)), where I_{b} is the constant bias offset current and Iₘ(t) is the modulation current to create frequency sweeps. This non-linearity results in the non-linear SL frequency sweep when SL is driven by the linear Vᵢ sweep shown in FIG. 3-A. When such nonlinear SL frequency sweep is used in an FMCW lidar, the spectrum of the electronic lidar return signal is broadened (poor spatial resolution) and has low power (poor sensitivity) as shown in FIG. 3-D. This signal is not generally desirable for the FMCW lidar and the spectrum demonstrates the need to generate the linear SL frequency sweep.

The goal of the algorithm is to find such a current modulation function Iₘ(t)=aVᵢ; that provides a desired SL frequency modulation function δƒ(t). Since the desired frequency modulation function is known (linear in this case, proportional to Vᵢ which is defined as a linear saw-tooth sweep), the corresponding etalon transmission function ηᵢ⁰ is also known from Eq. 1. To achieve the desired current modulation function one starts with an arbitrary (e.g. linear) current modulation function Vᵢ and measures the corresponding etalon transmission function ηᵢ. The algorithm then adjusts Vᵢ until the difference between the desired ηᵢ⁰ and measured ηᵢ is below some threshold for all i. Since we constrained the SL bias and modulation current to the range where η is a single-valued function of δƒ(t) (Eq. 3), equality of Θᵢ and ηᵢ⁰ implies equality of Fₘ(I_{b}+Iₘ⁰(t)) and the desired ƒ₀+δƒ(t).

In some SLs, the change in bias current leads to changes in both optical frequency and output power. For every possible or required value of δƒ one can measure the SL power variations and normalize (divide) the measured etalon transmission by the measured power values Pᵢ, and by the maximum etalon transmission value ηₘₐₓ^{ADC} determined from the calibration step above to directly obtain the values of η normalized to 1 as in Eq. (1). A more detailed explanation of this step is as follows. The linear current modulation signal is proportional to the voltage signal shown in FIG. 3-A. The resulting SL power signal is recorded by the signal processing system 216 in step 510 as shown in FIG. 3-B. The digitized electronic etalon transmission signal is also recorded in step 510 as shown in FIG. 3-C. Using the power signal and the calibration value ηₘₐₓ^{ADC}, the etalon signal in FIG. 3-C is normalized to 1 as in Eq. (1) to obtain ηᵢ in step 512.

In step 514, from the obtained values of η₀ and η_{N-1} and equation (4), one finds the boundary values δƒ₀, δƒ_{N-1} and all the remaining values in between according to e.g. the desired linear frequency sweep function:

δƒᵢ=δƒ₁+i·(δƒ_{N-1}−δƒ₁)/(N−1), (5)

where i∈[0, N−1] and N is the number of data points in each up-chirp or down-chirp. It's worth noting that it is easier to work not with the absolute values of δƒ but rather with the values of the argument of the sin function from Eq. 1.

The etalon transmission values corresponding to the desired linear sweep (5) values are now computed in step 516 according to Eq. (1) as ηᵢ⁰(δƒᵢ). Fractional error values are computed in step 518 to quantify the deviation of the etalon transmission induced by the linear bias current sweep from the one induced by the linear frequency sweep:

ϵᵢ=(ηᵢ−ηᵢ⁰)/ηᵢ (6)

One can now modify the linear current sweep such that ϵᵢ gets minimized for all i. If this is achieved, the resulting etalon transmission will follow the function corresponding to the linear frequency sweep. Since our etalon transmission function is single-valued, this means that the frequency sweep is linear. The voltage that controls the current sweep can be modified in step 522 with the following update rule:

Vᵢ=Vᵢ−k(N−1)ϵᵢα, (7)

where α is an empirically determined parameter that provides optimum convergence of the algorithm. Also the sign of α must be correct for convergence. Now the SL is driven with a nonlinear current sweep but the etalon transmission resulting from this nonlinear sweep is closer to the one which would have resulted if the SL frequency were swept linearly. These etalon transmission values ηᵢ resulting from the modified current sweep values are now measured again and the procedure to adjust Vᵢ is repeated until all ϵᵢ are sufficiently small. In that case, the step 522 transitions to step 530. At that point the desired frequency chirp is achieved and the corresponding forcing function Vᵢ can be stored for later quick start or dynamically monitored and updated as needed.

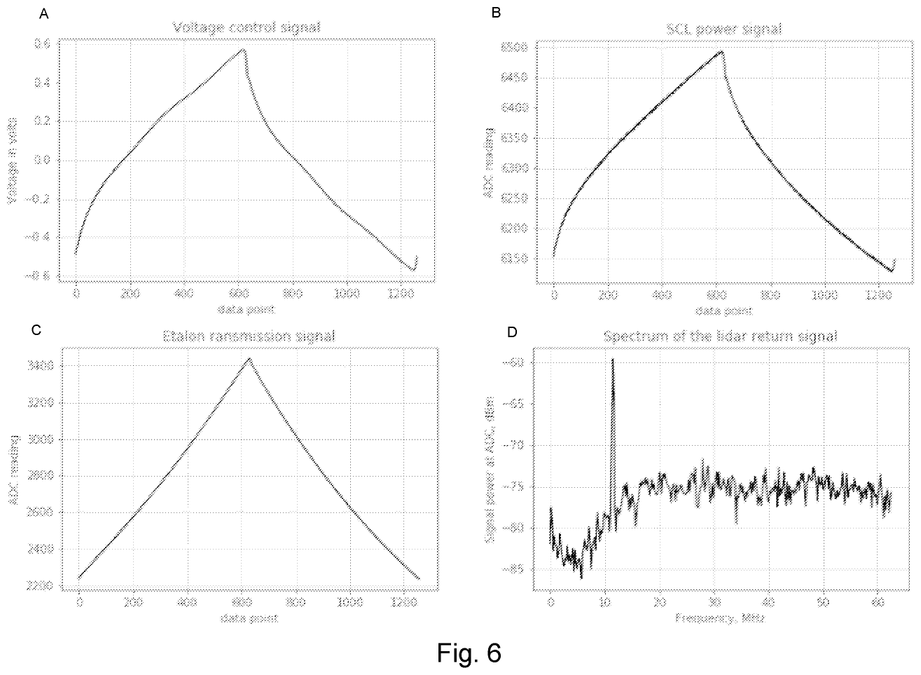

The steps of the software algorithm that implements the above descriptions and operates the embodiments are summarized as a flowchart in FIG. 5. The voltage control signal obtained by the algorithm for the particular hardware embodiment is shown in FIG. 6-A. The corresponding power signal is shown in FIG. 6-B, the etalon transmission signal is shown in FIG. 6-C. These signals correspond to linearized SL frequency sweep. This is evidenced by the spectrum of the FMCW lidar return signal which is now more narrow (high spatial and velocity resolution) and of higher power (high sensitivity) as shown in FIG. 6-D. Thus, the above equations and method were verified to generate a linear saw-tooth frequency chirp with the described apparatus, which is useful for FMCW lidar. Also the hardware needed for the resampling method mentioned above was also experimentally verified.

It is possible that other methods to derive the optimum voltage signal that results in linear frequency sweep can be used other than the iterative approach outlined above. It might be possible to derive the optimum sweep from a few measurements of the SL response to the linear current sweep via the etalon function. Alternatively a current oscillation at various frequencies or a current step (an abrupt change of current) can be applied to the SL and changes in its emission power and frequency can be measured with the apparatus described here. From these frequency response or step response functions it might be possible to compute the optimum current profile that results in arbitrary desired frequency sweep.

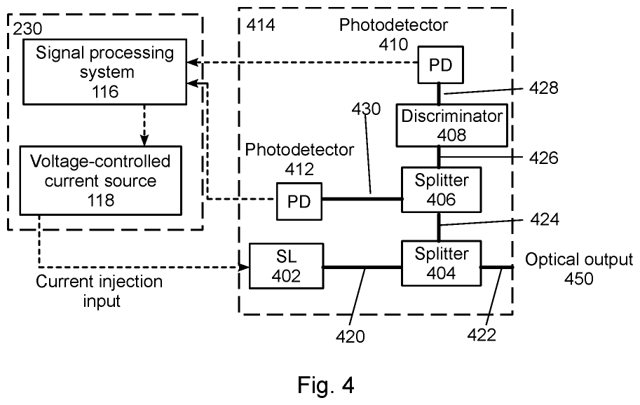

The etalon 210 in FIG. 2 can be replaced with any fiber-based or waveguidebased interferometer such as Mach-Zehnder or other type, which can provide the interference behavior similar to the one of a classical Fabry-Perot etalon. The laser and the detectors can be all integrated on a chip platform, or the standalone laser can be integrated with a chip platform by means of a coupling port. Thus, an embodiment integrated on a chip platform is possible, as schematically illustrated in FIG. 4. Here, the SL 402 can be integrated on a chip platform or be off-chip and coupled to the waveguides of the chip via coupling elements (not shown). The embodiment can include optical waveguides on a chip 420, 422, 424, 426, 428, 430 that physically connect various components on a chip and support an optical mode by which light can be transmitted through such waveguides. The arrows represent electronic signals and the blocks represent integrated photonic components on a chip. The splitter 404 directs a small portion of the major laser output towards another splitter 406 and also provides a major optical output 450. The splitter 406 separates the incoming signal into the power sensing signal carried by waveguide 430 and the frequency sensing signal carried by waveguide 426. The power sensing signal is transmitted by a waveguide 430 to the detector 412, and the frequency sensing signal is transmitted via waveguide 426 to discriminator 408 which can be a waveguide loop resonator or a waveguide interferometer for example. The signal transmitted by the discriminator 408 through the waveguide 428 is measured by the detector 410. The operation of this embodiment is conceptually similar to the operation of the other embodiment shown in FIG. 2.

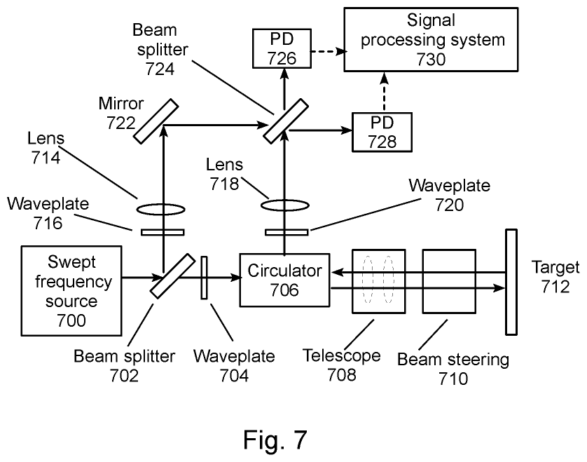

An exemplary FMCW lidar system implemented with free space optics and including an FMCW source embodiment similar to described above is shown as a block diagram in FIG. 7. Such lidar system was designed and built to test the arbitrary waveform generator embodiment described above. It includes the source 700 which provides the major power output which is received by a beam splitter 702. The splitter 702 deflects a portion of the major power output (typically a few percent) to become a local oscillator signal (LO). The system can include a half-wave plate 716 which can rotate the LO signal polarization plane. The system can further include a lens 714 that can be used to focus the LO signal on the detectors 726, 728. The mirror 722 is used to deflect the LO beam towards the beam splitter 724 which can have splitting ratio of about 50%. The system can include a half-wave plate 704 which can be used to control the polarization of the major power output. This may or may not be needed, as this polarization controls how the circulator 706 directs light, e.g. how much of the major power output is passed by it and how much is deflected. All wave-plates here are optional. The circulator 706 transmits the major power output towards the telescope 708 which shapes the beam and its wave front. The telescope passes the beam to the beam steering mechanisms 710 and the beam is sent to a remote target 712. The target scatters some of the light back towards the elements 710, 708 and 706. This scattered light becomes the optical lidar return signal as the circulator 706 now deflects this light towards the half-wave plate 720. The plate 720 passes light to lens 720 that focuses the lidar return optical signal onto the photodetectors 726, 728. The beamsplitter 724 splits both the LO and the optical lidar return signals into two beams nearly equal in power, so each of the photodetectors 726,728 receives half of each beam. The split LO and lidar return signals beams are made to overlap on the detectors. These detectors 726, 728 are connected in the balanced detector configuration and they provide the electronic signal to the signal processing system 730 which outputs the electronic lidar return signal.

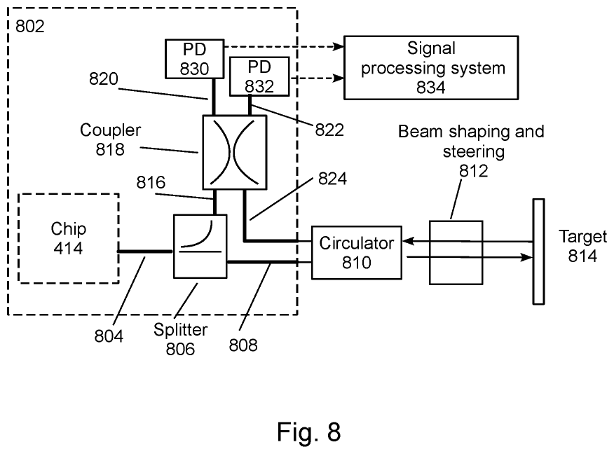

Referring now to FIG. 8, another example of a lidar system is shown based on integrated photonics and free space components. Here, the components depicted on chip 414 of FIG. 4 can be included on a chip 802 along with more components and waveguides to form a coherent transceiver. For example, an FMCW source 414 provides output beam that is transmitted on a chip by a waveguide 804 to a splitter 806 that passes majority of light to waveguide 808 to become major optical output. The amount of light diverted by the splitter 806 from waveguide 804 to waveguide 816 can be e.g 1-5% of the power carried by the waveguide 804. That light can be passed on to circulator 810 and the transmitted light is shaped and steered by elements 812. A portion of light reflected or scattered by a target 814 becomes the lidar optical return signal as it reaches the circulator 810. The circulator then couples that return signal into waveguide 824 where it travels to reach the coupler 818 that splits light from each of the waveguides 816 and 824 into about equal parts shared by waveguides 820 and 822. Thus, light from waveguide 816 is mixed with light from waveguide 824 and the mixture is equally split between waveguides 820 and 822. Detectors 830 and 832 convert that light into electronic signal which are processed by the signal processing system 834 to create useful FMCW lidar signals.

The processes described herein for controlling, creating and using a precise broadband optical waveform may be implemented via software and hardware. The signal processing system 216 or control system 230 can incorporate such software, firmware and hardware or other means, or a combination thereof. The signal processing system 216 or control system 230 can be part of a more general combination of software and hardware with additional functions. The examples of computing hardware components include a field-programmable gate array (FPGA) chip, an application specific integrated circuit (ASIC) chip, a central processing unit (CPU), analog to digital converters (ADC), digital to analog converter (DAC), a digital signal processor (DSP). A CPU can be a separate chip, be part of another chip or be implemented in an FPGA fabric. Such components can be used to record, process and produce electronic signals for the operation of embodiments of FMCW sources or lidar systems. Such example hardware for performing the described functions is detailed below.

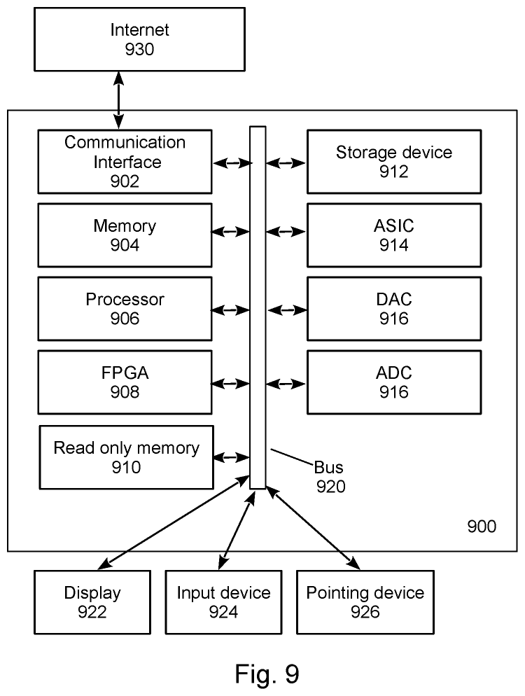

FIG. 9 illustrates computer system upon which an embodiment can be implemented. Computer system 900 includes a communication mechanism such as a bus 920 for passing information between other internal and external components of the computer system 900. Information (also called data) is represented as a physical expression of a measurable phenomenon, typically electric voltages, but including, in other embodiments, such phenomena as magnetic, electromagnetic, pressure, chemical, biological, molecular, atomic, sub-atomic and quantum interactions. For example, a zero and non-zero electric voltage, or south or north magnetic poles, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range. A bus 920 includes one or more parallel conductors of information so that information is transferred quickly among devices coupled to the bus 920. One or more processors 906 for processing information are coupled with the bus 920.

A processor 1 A processor 906 performs a set of operations on information. The set of operations include bringing information in from the bus 920 and placing information on the bus 920. The set of operations also typically include comparing two or more units of information, shifting positions of units of information, and combining two or more units of information, such as by addition or multiplication or logical operations like OR, exclusive OR (XOR), and AND. Each operation of the set of operations that can be performed by the processor is represented to the processor by information called instructions, such as an operation code of one or more digits. A sequence of operations to be executed by the processor 906, such as a sequence of operation codes, constitute processor instructions, also called computer system instructions or, simply, computer instructions. Processors may be implemented as mechanical, electrical, magnetic, optical, chemical or quantum components, among others, alone or in combination.

Computer system 900 also includes a memory 904 coupled to bus 920. The memory 904, such as a random access memory (RAM) or other dynamic storage device, stores information including processor instructions. Dynamic memory allows information stored therein to be changed by the computer system 900. RAM 904 allows a unit of information stored at a location called a memory address to be stored and retrieved independently of information at neighboring addresses. The memory 904 is also used by the processor 906 to store temporary values during execution of processor instructions. The computer system 900 also includes a read only memory (ROM) 910 or other static storage device coupled to the bus 920 for storing static information, including instructions, that is not changed by the computer system 900. Some memory is composed of volatile storage that loses the information stored thereon when power is lost. Also coupled to bus 920 is a non volatile (persistent) storage device 912, Such as a magnetic disk, optical disk or flash card, for storing information, including instructions, that persists even when the computer system 900 is turned off or otherwise loses power.

Information, including instructions, is provided to the bus 920 for use by the processor from an external input device 924, Such as a keyboard containing alphanumeric keys operated by a human user, or a sensor. A sensor detects conditions in its vicinity and transforms those detections into physical expression compatible with the measurable phenomenon used to represent information in computer system 900. Other external devices coupled to bus 920, used primarily for interacting with humans, include a display device 922, such as a liquid crystal display (LCD), a light emitting diode (LED) display or plasma screen or printer for presenting text or images, and a pointing device 926. Such as a mouse or a trackball or cursor direction keys, or motion sensor, for controlling a position of a small cursor image presented on the display 922 and issuing commands associated with graphical elements presented on the display 922. In some embodiments, for example, in embodiments in which the computer system 900 performs all functions automatically without human input, one or more of external input device 924, display device 922 and pointing device 926 is omitted.

In the illustrated embodiment, special purpose hardware, such as an application specific integrated circuit (ASIC) 914, is coupled to bus 920. The special purpose hardware is configured to perform operations not performed by processor 906 quickly enough for special purposes. Examples of application specific ICs include graphics accelerator cards for generating images for display 922, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 900 also includes one or more instances of a communications interface 902 coupled to bus 920. Communication interface 902 provides a one-way or two-way communication coupling to a variety of external devices that operate with their own processors, such as printers, scanners and external disks. In general the coupling is with a network link that is connected to a local or global network (internet 930) to which a variety of external devices with their own processors are connected. For example, communication interface 902 may be a parallel port or a serial port or a universal serial bus (USB) port on a personal computer. In some embodiments, communications interface 902 is an integrated services digital network (ISDN) card or a digital subscriber line (DSL) card or a telephone modem that provides an information communication connection to a corresponding type of telephone line. In some embodiments, a communication interface 902 is a cable modem that converts signals on bus 920 into signals for a communication connection over a electric cable or into optical signals for a communication connection over a fiber optic cable. As another example, communications interface 902 may be a local area network (LAN) card to provide a data communication connection to a compatible network, such as ethernet or internet 930. Wireless links may also be implemented. For wireless links, the communications interface 902 sends or receives or both sends and receives electrical, acoustic or electromagnetic signals, including infrared and optical signals, which carry information streams, such as digital data. For example, in wireless handheld devices, such as mobile telephones like cell phones, the communications interface 902 includes a radio band electromagnetic transmitter and receiver called a radio transceiver.

The term computer-readable medium is used herein to refer to any medium that participates in providing information to processor 906, including instructions for execution. Such a medium may take many forms, including, but not limited to, non-volatile media, volatile media and transmission media. Common forms of computer-readable media include, for example, a floppy disk, a flexible disk, a hard disk, a magnetic tape, or any other magnetic medium, a compact disk ROM (CD-ROM), a digital video disk (DVD) or any other optical medium, punch cards, paper tape, or any other physical medium with patterns of holes, a RAM, a program mable ROM (PROM), an erasable PROM (EPROM), a FLASH-EPROM, or any other memory chip or cartridge, a transmission medium such as a cable or carrier wave, or any other medium from which a computer can read.

Logic encoded in one or more tangible media includes one or both of processor instructions on a computer-readable storage media and special purpose hardware, Such as ASIC 914. A field programmable gate array (FPGA) 908 is a set of connections (gates) on a chip that can be programmed to form various complex connections and thus implement arbitrary digital circuits from simple ones to complex one such as ASIC or a CPU. The FPGA 908 can read its configuration from a computer readable media or from a storage device 912 or from a communication interface 902 or from ROM 910.

Analog to digital converters (ADC) and digital to analog converters (DAC) can be part of some other chips or separate chips. The ADC converts the voltages present at its input into digital representation such as data that can be passed to other components via bus 920 or through direct connections to some devices such as ASICs or FPGA. Similarly, the DAC 916 implements conversion of digital representation of voltages into physical voltages on its output lines.

At least some embodiments described here are related to the use of computer system 900 for implementing some or all of the techniques described herein. According to one embodiment of the invention, those techniques are performed by computer system 900 in response to processor 906 executing one or more sequences of one or more processor instructions contained in memory 904. Such instructions, also called computer instructions, software and program code, may be read into memory 904 from another computer-readable medium such as storage device 912 or a communication device 902. Execution of the sequences of instructions contained in memory 904 causes processor 906 to perform one or more of the method steps described herein. In alternative embodiments, hardware, such as ASIC 914 or FPGA 908 may be used in place of or in combination with software to implement the embodiments of an FMCW laser source. Thus, embodiments of the are not limited to any specific combination of hardware and software, unless otherwise explicitly stated herein.

The high sweep rate FMCW sources described here have applications in FMCW systems wherein precise and fast control of optical frequency is necessary. In particular, FMCW-based lidar for real-time high resolution imaging will benefit from the high rate of sweep repetition. The sweep amplitude is also of practical importance because the range resolution ΔZ of an FMCW range measurement is ultimately determined by the total frequency excursion B of the optical source during each sweep, ΔZ=c/2B, where c is the speed of light. The resolution here is the ability of an FMCW system to identify two close but distinct targets separated by ΔZ. The systems and methods described here provide a simple and manufacture-friendly way to build FMCW lidar for automotive, drone and other applications. It's likely that simplicity of embodiments will lead to cost advantage. A lower cost lidar with technical specifications sufficient for any particular application will be desirable in the market.

In Summary, techniques to produce quickly repeating broadband arbitrary and, in particular, linear frequency sweeps with semiconductor laser diodes are disclosed herein. At least one embodiment of a laser system generates accurate and broadband frequency sweeps using laser injection current signal shaping relying upon an optical etalon as a frequency discriminator. Periodic frequency sweeps of about 1 GHz of optical frequency excursion in about 5 microseconds with deviation from linearity of less than 1% are achieved. This enabled new imaging lidar architecture for automotive and other applications.

The specifics of the above descriptions should not be construed as limitations on the scope, but rather an exemplification of one [or several] embodiment(s) thereof. Many other variations are possible. For example, an optical waveform generator utilizing a non-semiconductor laser such as a laser with solid, crystalline, gaseous or liquid gain medium. A generator can be based on a non silicon photonics chip such an InP chip or other III/V semiconductor. A generator can be implemented without an isolator or a power measuring photodetector. A signal processing system can be integrated on the same chip platform as the laser and other components, or on a separate chip. A voltage-controlled current source can be a separate component or can be integrated with the signal processing system as its part within the system controller. The described method can be used regardless of any particular laser tuning mechanism.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims. Furthermore, to the extent that the term “includes” is used in either the details description or the claims, such term is intended to be inclusive in a manner similar to the term “comprising” as “comprising” is interpreted when employed as a transitional word in a claim.

What is claimed is:

1. A method of generating a swept frequency signal using an optical laser having an injection current input to provide an inherently nonlinear response comprising:
(a) generating a coherent optical laser beam subject to optical frequency nonlinearity;
(b) dividing the laser beam into a power beam comprising a substantial majority of the laser output and a feedback beam comprising the remainder of the laser output;
(c) converting the feedback beam into a discriminator beam by means of an optical discriminator characterized by a predetermined relationship between the frequency of the feedback beam and a ratio of the power of the discriminator beam to the power of the feedback beam;
(d) constraining the frequency of the coherent optical laser beam to a range of values such that said predetermined relationship connects any value from the range to a unique corresponding value of said ratio;
(e) applying a predetermined initial signal to the injection current input and recording an electronic discriminator signal which is proportional to the power of the discriminator beam;
(f) computing a target electronic discriminator signal corresponding to the frequency of said swept frequency signal as a function of time;
(g) computing a final signal such that when it is applied to the injection current input the resulting electronic discriminator signal is substantially similar to the target electronic discriminator signal
whereby the swept frequency signal with a predetermined chirp is obtained.

2. The method of claim 1, further comprising splitting a portion from the feedback beam into a power sensing beam and recording an electronic power signal proportional to the power of the power sensing beam; said electronic power signal is used in computing of the final signal.

3. The method of claim 1, wherein the sweep cycle of the laser is varied in a selectable fashion, to provide a linear optical frequency variation as a function of time.

4. The method of claim 1 wherein the final signal is adjusted to compensate for optical frequency nonlinearities in the laser output.

5. The method of claim 1 wherein computing of said final signal is accomplished by an iterative procedure.

6. The method of claim 1, wherein said discriminator is a Fabry-Perot etalon with distance between its reflecting surfaces of 0.1-10 mm.

7. The method of claim 1, wherein said discriminator is a Mach-Zehnder interferometer with the length difference between its arms of 1-50 mm.

8. The method of claim 1, wherein said discriminator is a waveguide loop resonator with resonance full width at half maximum of 1-100 GHz.

9. A laser system providing an agile, high coherence, swept frequency optical output at a high repetition rate with precise control over a wide frequency range, comprising:
a semiconductor laser emitting in the optical spectrum, said laser including an injection current input and providing an output of controllable frequency in response thereto;
the feedback circuit including a signal divider receiving the laser output and providing a major power output signal and a feedback signal therefrom;
a discriminator receiving the feedback signal from the signal divider and providing an optical discriminator signal that varies in accordance with the laser output frequency;
a detector converting the optical discriminator signal into an electronic discriminator signal;
a control system receiving the electronic discriminator signal and having an output coupled to the injection current input of the semiconductor laser to provide precise control signal to cause the optical frequency of the semiconductor laser to change in a substantially predetermined way.

10. A laser system of claim 9, further comprising a second signal divider splitting a power sensing signal from the fractional feedback signal and; a second detector converting the power sensing signal into an electronic power sensing signal and; said electronic power sensing signal used by the control system along with the electronic discriminator signal.

11. A laser system of claim 9, wherein the control system calculates the form of the precise control signal iteratively by comparing the electronic discriminator signal in response to the precise control signal to the electronic discriminator signal in response to the substantially predetermined way of change of the laser frequency.

12. A laser system of claim 9, wherein the optical frequency of the semiconductor laser is caused to sweep with a linear chirp.

13. The laser system of claim 12, wherein the chirp spans at least about 1 GHz in no more than about 5 microseconds while deviating from linear chirp by less than about 1%.

14. he laser system of claim 9, wherein said discriminator is a Fabry-Perot etalon with distance between its reflecting surfaces of 0.1-10 mm.

15. he laser system of claim 9, wherein said discriminator is a Mach-Zehnder interferometer with the length difference between its arms of 1-50 mm.

16. he laser system of claim 9, wherein said discriminator is a waveguide loop resonator with resonance full width at half maximum of 1-100 GHz.

17. A method of obtaining a measure of instantaneous frequency changes of a laser during an optical frequency sweep comprising:
(a) generating a coherent optical laser beam;
(b) dividing the laser beam into a power beam comprising a substantial majority of the laser output and a feedback beam comprising the remainder of the laser output;
(c) dividing the feedback beam into a power sensing beam and a frequency sensing beam;
(d) converting the frequency sensing beam into a discriminator beam by means of an optical discriminator characterized by a predetermined relationship between the frequency of the frequency sensing beam and a measurable quantity provided by the discriminator;
(e) constraining the frequency of the laser beam to a range of values such that said predetermined relationship connects any value from the range to a unique corresponding value of said quantity;
(f) simultaneously recording an electronic power signal which is proportional to the power of the power sensing beam and an electronic discriminator signal which is proportional to the power of the discriminator beam;
(g) computing said measure of instantaneous frequency changes of the optical frequency during the sweep from the recorded electronic discriminator signal and the electronic power signal;
wherein the measured instantaneous frequency information is used to resample a recorded interferometric lidar return signal originating from the interference of a local oscillator signal and a target return signal.

18. The method of claim 17, wherein said discriminator is a Fabry-Perot etalon with distance between its reflecting surfaces of 0.1-10 mm.

19. The method of claim 17, wherein said discriminator is a Mach-Zehnder interferometer with the delay between its arms of 10-100 mm

20. The method of claim 17, wherein the measurable quantity provided by the discriminator is a ratio of the power of a beam received by the discriminator to the power of a beam transmitted by the discriminator.
